(19) United States
(12) Patent Application Publication
(10) Pub. No.: US 2003/0207558 A1
(43) Pub. Date: Nov. 6, 2003

(54) Method forming copper containing semiconductor features to prevent thermally induced defects

(75) Inventors: Tien-I Bao, Hsin-Chu (TW); Syun-Ming Jang, Hsin-Chu (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/139,976

(22) Filed: May 6, 2002

(51) Int. Cl. H01L 21/4763; H01L 21/44

(52) U.S. Cl. 438/622; 438/643; 438/687; 438/648

(57) ABSTRACT

A method for forming a copper containing semiconductor feature to prevent thermally induced defects in including: (a) providing an anisotropically etched opening formed in a dielectric insulating layer; (b) conformally depositing a barrier layer over the anisotropically etched opening; (c) conformally depositing a copper portion to fill a portion of the anisotropically etched opening with copper; and, (d) repeating steps b and c at least once to completely fill the anisotropically etched opening to form a copper filled semiconductor feature.

### FIELD OF THE INVENTION

This invention generally relates to the formation of copper containing semiconductor features and more particularly to a method for forming copper containing semiconductor features to prevent or avoid the formation of thermally induced defects in subsequent processing steps.

### BACKGROUND OF THE INVENTION

Multi-level metallization is one of the key technologies for the next generation of ultra large scale integration (ULSI). The multilevel interconnects providing electrical interconnection between various portions of a semiconductor device that form the basis of this technology require increasingly complicated manufacturing processes to avoid new problems engendered by the adoption of new manufacturing processes driven by the goals of reliability, low resistance and low capacitance electrical properties, and structurally stable semiconductor features. Many of the interconnect features include high aspect ratio apertures, including contact holes, vias, metal interconnect lines (trench lines) and other features. Also included are features having larger dimensions including trench lines and bonding pads. Reliable formation of these interconnect features including structural stability when exposed to various processing steps is critical to the formation of reliable semiconductor devices.

Copper and copper alloys have become the metal of choice for forming many interconnect features on semiconductor substrates. Copper and its alloys have lower resistivity and higher electromigration resistance compared to other metals such as, for example, aluminum. These characteristics are critical for achieving higher current densities including increased device speed.

Electroplating (electrodeposition) or electroless plating, particularly with respect to copper containing semiconductor features are being established as preferable methods for filling semiconductor device metal interconnect features to form structures including vias trench lines, and bonding pads. Typically, electroplating uses a suspension of positively charged ions of deposition material, for example metal ions, in contact with a negatively charged substrate, as a source of electrons, to deposit (plate out) the metal ions onto the charged substrate, for example, a semiconductor wafer. A thin metal layer (seed layer) is first deposited on the semiconductor wafer and within etched features to provide an electrical path across the surfaces. An electrical current is supplied to the seed layer whereby the semiconductor wafer surface is electroplated with an appropriate metal, for example, aluminum or copper.

One exemplary process for forming a series of interconnected multiple layers, for example, is a damascene process. Although there are several different manufacturing methods for manufacturing damascene structures, all such methods employ a series of photolithographic masking and etching steps, typically including a reactive ion etch (RIE). In the typical multilayer semiconductor manufacturing process, for example, a series insulating layers are deposited to include a series of interconnecting metallization structures such as vias and metal line interconnects (trench lines) to electrically interconnect areas within the multilayer device and bonding pads to interconnect the various devices on the chip surface or to interconnect the device to a semiconductor packaging frame. For example, pluralities of vias are separated from one another along the semiconductor wafer and selectively interconnect conductive regions between layers of a multi layer device. Metal interconnect lines (trench lines) typically serve to selectively interconnect conductive regions within a layer of a multilayer device.

In forming a typical metal interconnect feature, feature openings are etched into one or more insulating layers and are back-filled with metal, for example copper. The insulating layers (IMD layers) are typically a low-k (low dielectric constant) insulating material which reduces signal delay times caused by parasitic capacitance. The process by which feature openings are selectively etched into the insulating layers is typically a photolithographic patterning process, followed by a reactive ion etch (RIE) process, both of which are commonly known in the art.

In filling the semiconductor feature openings with metal, for example, copper, electroplating is a preferable method to achieve superior step coverage of etched features. The method generally includes first depositing a barrier/adhesion layer, for example, tantalum nitride over the etched feature opening surfaces, depositing a metal seed layer, for example copper, over the barrier/adhesion layer by physical vapor deposition (PVD) or chemical vapor deposition (CVD), followed by electroplating a metal, for example copper, over the seed layer to fill the etched features. The excess electroplated copper overlying the features is then planarized, for example, by chemical mechanical polishing (CMP), to define an electrically conductive interconnect feature.

Metal electroplating in general is a well-known art and can be achieved by a variety of techniques. Common designs of cells for electroplating a metal on semiconductor wafers involve positioning the plating surface of the semiconductor wafer within an electrolyte solution including an anode with the electrolyte impinging perpendicularly on the plating surface. The plating surface is contacted with an electrical power source forming the cathode of the plating system such that ions in the plating solution deposit on the conductive portion of the plating surface. Alternatively, spontaneous electrodeposition without an applied potential can occur if thermodynamically favorable conditions exist with respect to the substrate and electroplating solution which are conducive to spontaneous electrodeposition (electroless plating).

One problem with the prior art copper containing semiconductor feature formation process includes the structural instability of relatively large copper containing features, for example including dimensions greater than about 1 micron including, for example, features such as wide trench lines and bonding pads. In particular, the copper layers tend to form defects including protrusions also referred to as hillcocks at the feature surfaces following exposure to high temperatures, for example, greater than about 250° C. (Inventor note: adjust as necessary) Semiconductor manufacturing processes following formation of the copper containing feature includes several subsequent high temperature process including for example, metal nitride deposition, that frequently cause the formation of thermally induced defects in the copper containing features.

There is therefore a need in the semiconductor processing art to develop a method whereby copper containing semiconductor features may be formed to avoid or prevent formation of thermally induced defects during subsequent processing steps.

It is therefore an object of the invention to provide a method whereby copper containing semiconductor features may be formed to avoid or prevent formation of thermally induced defects during subsequent processing steps while overcoming other deficiencies and shortcomings of the prior art.

### SUMMARY OF THE INVENTION

To achieve the foregoing and other objects, and in accordance with the purposes of the present invention, as embodied and broadly described herein, the present invention provides a method for forming a copper containing semiconductor feature to prevent thermally induced defects.

In a first embodiment, the method includes (a) providing an anisotropically etched opening formed in a dielectric insulating layer; (b) conformally depositing a barrier layer over the anisotropically etched opening; (c) conformally depositing a copper portion to fill a portion of the anisotropically etched opening with copper; and, (d) repeating steps b and c at least once to completely fill the anisotropically etched opening to form a copper filled semiconductor feature.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIGS. 1A-1F are representative cross sectional side view representations of portions of multilayer semiconductor device at stages in a manufacturing process according to the present invention.

FIG. 2 is a representative process flow diagram including several embodiments of the method according to the present invention.

### DETAILED DESCRIPTION OF THE PREFERRED EMBODIMENTS

Although the method of the present invention is explained with reference to formation of copper containing semiconductor features having a relatively large area, for example greater than about 1 micron in thickness, including for example bonding pads, contact pads, and large trenches, it will be appreciated that the method of the present invention may be advantageously adapted to smaller semiconductor features, including for example, dual damascene structures including the larger dimension trench lines overlying the via openings. By use of the term “copper” herein is included copper or alloys thereof.

In a first embodiment of the present invention, an anisotropically etched semiconductor feature opening is formed in a dielectric insulating material is provided including a first conformally (blanket) deposited barrier layer over the anisotropically etched opening. A portion of the anisotropically etched opening is then conformally filled with a first copper filling portion followed by forming a second conformally deposited barrier layer over the first copper filling portion. A remaining portion of the anisotropically etched opening is then conformally filled with at least a second copper filling portion to complete the filling of the copper feature. The process of forming barrier layer and depositing a copper portion may optionally be repeated more than once to form a copper filled semiconductor feature. Conventional planarizing processes including chemical mechanical polishing (CMP) are then carried out to remove excess copper and barrier layer material overlying the dielectric insulating layer to planarize and complete the formation of the copper filled (containing) semiconductor feature.

In other embodiments, the first and second (subsequent) barrier layers are formed of at least one of a refractory metal and refractory metal nitride including for example, tantalum, titanium, tungsten, and nitrides thereof, for example TaN, Tin, and WN. Preferably, the barrier layers including the first and second (subsequent) barrier layers are formed having a thickness of from about 25 Angstroms to about 500 Angstroms, more preferably, from about 50 Angstroms to about 100 Angstroms.

In another embodiment, an electrodeposition process, for example, at least one of an electroplating and electroless plating process is used for depositing the copper filling portions including the first and second copper filling portions to include the formation of a seed layer, for example copper, over the first and second barrier layers prior to the copper electrodeposition process.

In another embodiment, the first copper filling portion includes having a conformally deposited thickness ranging from about 25% to about 85% of the depth of the semiconductor feature. By the term ‘depth’ is meant the dimension of the semiconductor feature opening in a direction perpendicular to the process surface of a semiconductor wafer.

In one embodiment, the semiconductor feature is a bonding pad or contact pad including a depth of at least about 1 micron. More preferably, the depth of the bonding pad or contact pad is from about 1 to about 5 microns.

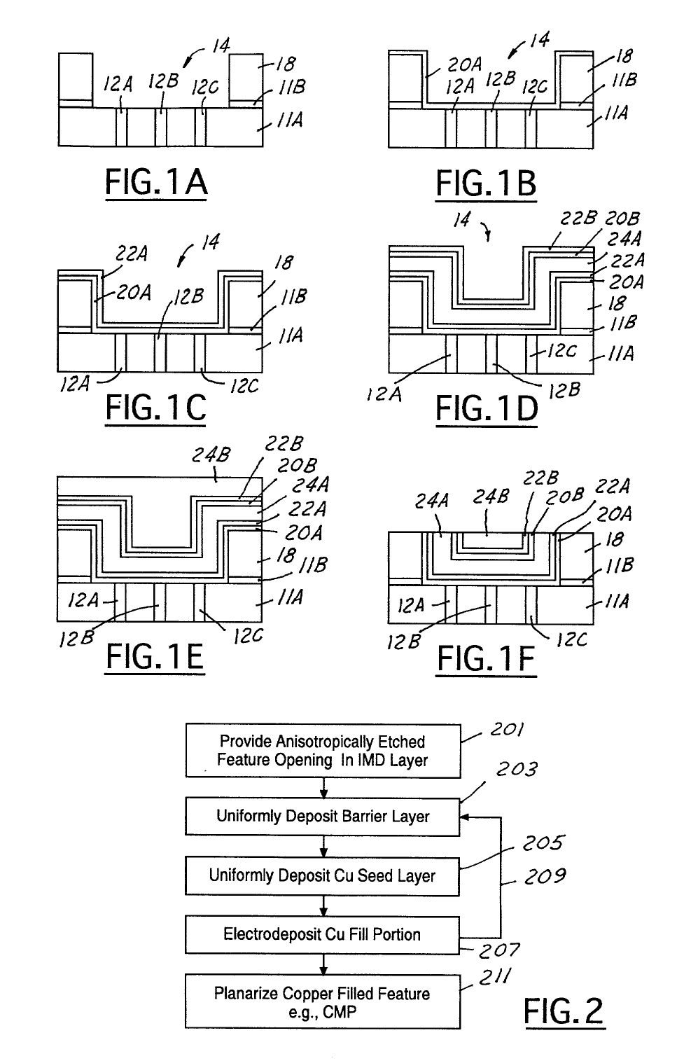

Referring to FIG. 1A, in an exemplary embodiment of the present invention is shown a portion of a multi-level semiconductor feature at stages in manufacture of an exemplary copper containing (filled) semiconductor feature 10, for example, a bonding or contact pad. Shown in FIG. 1A is anisotropically etched pad opening 14 formed in dielectric insulating layer 18A, also referred to as an inter-metal dielectric (IMD) layer, for example, formed of a low-k (low dielectric constant) insulating material. The pad opening 14, forms closed communication with electrically conductive interconnect lines, for example copper vias 12A, 12B, and 12C formed in an underlying IMD layer 11A. An etching stop layer 11B, for example, silicon nitride or silicon oxynitride is optionally provided between IMD layers 18A and 11A. There are several suitable low-k materials that may be used for forming the IMD layers including for example, carbon doped oxide and fluorinated silica glass (FSG). It will be appreciated that the method of the present invention may be advantageously used with any dielectric insulating layer including low-k IMD layers where protection of the layer from in-diffusion of subsequently filled copper would be advantageous.

Still referring to FIG. 1A, the IMD layers are formed by conventional methods including CVD processes including plasma enhanced CVD (PECVD), high density plasma CVD (HDP-CVD), or spin on methods where, for example, spin-on glass (SOG) is used to form the IMD layer. The etching stop layer is typically formed by a conventional low pressure CVD (LPCVD) or PECVD process. The etching stop layer 11B is typically formed having a thickness of about 200 Angstroms to about 1000 Angstroms. The pad opening 14 is typically formed after photolithographically patterning the pad opening and anisotropically etching the pad opening by a conventional anisotropic plasma etching processes, for example, including fluorocarbons as etching gases. The pad opening 14 is anisotropically etched to form closed communication with electrically conductive interconnect lines 12A, 12B, 12C.

Referring to FIG. 1B, in one embodiment of the present invention, a first barrier layer 20A is conformally deposited over the pad opening 14 by a conventional CVD process including for example, LPCVD, PECVD. It will be appreciated that a barrier layer of refractory metal may first be deposited by a physical vapor (PVD) deposition process optionally followed by a gaseous nitridization process to form a refractory metal nitride, the method well known in the art. Preferably, the barrier layer is at least one of a refractory metal and refractory metal nitride. Preferably, the refractory metal and refractory metal nitride do not readily form copper alloys, for example, at temperatures less than about 800° C. Preferably, the refractory metal includes at least one of tantalum, titanium, tungsten, and the refractory metal nitride, nitrides thereof, for example TaN, TiN, and WN. The barrier layer 20A is preferably formed having a thickness between about 25 Angstroms and about 500 Angstroms, more preferably, about 50 Angstroms to about 100 Angstroms.

Following formation of the barrier layer 20A, pad opening 14 is filled with copper. Although there are various methods for filling the pad opening with copper including for example, PVD, CVD, and electrodeposition, an electrodeposition method, while not necessary for the practice of the present invention, is a preferred embodiment. For example, an electrodeposition process including electroplating copper onto a metal seed layer, for example copper, is preferable to achieve better step coverage of the copper.

Referring to FIG. 1C, in order to carry out an electrodeposition process to fill the pad opening with metal, a metal seed layer 22A, for example copper, according to an embodiment of the present invention, is blanket deposited, for example by CVD or PVD over the barrier layer 20A. The seed layer 22A provides good adhesion and an electrically conductive layer for a cathodic reaction in an electroplating process where copper ions in an electroplating solution (electrolyte) are deposited out of solution onto the seed layer 22A. The thickness of the seed layer 22A may vary between about 200 angstroms and 1000 angstroms depending upon process constraints.

Referring to FIG. 1D, in one embodiment of the present invention, following formation of the seed layer 22A, an electrodeposition process is carried out to partially fill the pad opening with a first conformally deposited copper layer 24A. Preferably, the pad opening 14 is filled with a first copper portion having a thickness of about 25 percent to about 85 percent of the feature opening depth (e.g., pad opening 14). For example, the opening depth may range from about 1 micron to about 5 microns in typical contact or bonding pads.

Still referring to FIG. 1D, following electrodeposition of copper layer 24A, in one embodiment of the present invention, a second barrier layer 20B including the preferred embodiments detailed for the first barrier layer 20A is formed over copper layer 24A followed by formation of an overlying second seed layer 22B also including the preferred embodiments detailed for the first seed layer 22A.

Referring to FIG. 1E, following formation of second barrier layer 20B and second seed layer 22B, an electrodeposition process as previously outlined for forming copper layer 24A is carried out to conformally deposit copper layer 24B to fill a remaining portion of the pad opening 14.

Following copper filling of the pad opening, a conventional copper CMP process is carried out to remove excess copper in copper layer 24A and 24B overlying IMD layer 18 and to planarize the copper filled semiconductor feature. In the process, the second barrier layer 20B and first barrier layer 20A are also removed over the upper surface of IMD layer 18 to form a planar surface defining the copper filled contact pad.

Referring to FIG. 2 is a process flow diagram including several embodiments of the present invention. In process 201 are included processes for forming an anisotropically etched feature opening in a dielectric insulating layer, for example, an IMD layer. In process 203 a first barrier layer including at least one of a refractory metal and refractory metal nitride is conformally deposited over the anisotropically etched semiconductor feature. In process 205 a first copper seed layer is conformally deposited over the barrier layer for carrying out an electrodeposition process. In process 207, an electrodeposition process is carried out to conformally deposit a first copper fill portion filling a portion of the semiconductor feature. As indicated by direction process arrow 209, steps 203, 205, and 207 are repeated at least once to completely fill the semiconductor feature with copper according to a conformal electrodeposition process. Following copper filling of the semiconductor feature, a copper CMP process is carried out in process 211 to remove excess copper above the dielectric insulating layer including intervening barrier layers.

Thus, a method has been presented for preventing thermally induced defects in a copper containing semiconductor feature in subsequent semiconductor manufacturing steps, for example metal nitride deposition, thereby exposing the copper containing semiconductor features to elevated temperatures, for example, less than about 800° C. As a result, structural stability of the copper containing semiconductor feature is improved and thermally induced defects leading to decreased electrical performance reliability in semiconductor devices are avoided. An added benefit of the present invention is that the method results in the limitation of copper grain growth in subsequent exposure to elevated temperatures, thereby improving electrical performance and structural stability.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A method for forming a copper containing semiconductor feature to prevent thermally induced defects in comprising the steps of:
(a) providing an anisotropically etched opening formed in a dielectric insulating layer;
(b) conformally depositing a barrier layer over the anisotropically etched opening;
(c) conformally depositing a copper portion to fill a portion of the anisotropically etched opening with copper; and,
(d) repeating steps b and c at least once to completely fill the anisotropically etched opening to form a copper filled semiconductor feature.

2. The method of claim 1, wherein step b is followed by conformal deposition of a seed layer for carrying out a copper electrodeposition process.

3. The method of claim 2, wherein the copper electrodeposition process is carried out in step c to conformally deposit the copper portion.

4. The method of claim 3 wherein the electrodeposition process includes at least one of electroplating and electrodeposition.

5. The method of claim 1, wherein the barrier layer includes at least one of a refractory metal and refractory metal nitride.

6. The method of claim 5, wherein the refractory metal includes at least one of tantalum, titanium, and tungsten and the refractory metal nitride includes nitrides thereof.

7. The method of claim 5, wherein the barrier layer is formed to have a thickness of about 25 Angstroms to about 500 Angstroms.

8. The method of claim 1, wherein the copper portion includes a first deposited copper portion having a thickness of from about 25 percent to about 85 percent of a depth of the anisotropically etched opening.

9. The method of claim 8, wherein the depth is greater than about 1 micron.

10. The method of claim 3, wherein steps b and c are sequentially repeated once to form a first barrier layer and first seed layer followed by a first copper portion and a second barrier layer and second seed layer followed by a second copper portion.

11. The method of claim 1, further comprising a copper mechanical polishing (CMP) step following completely filling the anisotropically etched opening to planarize the copper filled semiconductor feature.

12. A method for forming copper containing semiconductor features to prevent thermally induced defects in subsequent processing steps comprising the steps of:
providing an anisotropically etched opening formed in a dielectric insulating layer;
blanket depositing a first barrier layer including at least one of a refractory metal and refractory metal nitride over the first copper portion over the anisotropically etched opening;
blanket depositing a first copper portion to fill a first portion of the anisotropically etched opening with copper;
blanket depositing a second barrier layer including at least one of a refractory metal and refractory metal nitride over the first copper portion; and,
blanket depositing a second copper portion to completely fill the anisotropically etched opening with copper to form a copper containing semiconductor feature.

13. The method of claim 1, wherein a first copper seed layer is blanket deposited prior to blanket depositing the first copper portion according to a first electrodeposition process and a second copper seed layer is blanket deposited prior to blanket depositing a second copper portion according to a second electrodeposition process.

14. The method of claim 13 wherein the electrodeposition process includes one of electroplating and electrodeposition.

15. The method of claim 12, wherein the refractory metal includes at least one of tantalum, titanium, and tungsten and the refractory metal nitride includes nitrides thereof.

16. The method of claim 15, wherein the barrier layer is formed to have a thickness of about 25 Angstroms to about 500 Angstroms.

17. The method of claim 12, wherein the first copper portion has a thickness of from about 25 percent to about 85 percent of a depth of the anisotropically etched opening.

18. The method of claim 17, wherein the depth is greater than about 1 micron.

19. The method of claim 12, further comprising a copper mechanical polishing (CMP) step following formation of the copper containing semiconductor feature to planarize the copper containing semiconductor feature.

20. The method of claim 19, wherein the copper containing semiconductor feature is subjected to temperatures of less than about 800 degrees Centigrade in subsequent processing steps.
